(19) United States
(12) Patent Application Publication
(10) Pub. No.: US 2021/0118652 A1
(43) Pub. Date: Apr. 22, 2021

(54) SUBSTRATE SUPPORT ASSEMBLY, SUBSTRATE PROCESSING APPARATUS, AND SEALING MEMBER

(71) Applicant: Tokyo Electron Limited, Tokyo (JP)

(72) Inventor: Kota YACHI, Miyagi (JP)

(21) Appl. No.: 17/070,185

(22) Filed: Oct. 14, 2020

(30) Foreign Application Priority Data
Oct. 21, 2019 (JP) 2019-191998

(51) Int. Cl. H01J 37/32

(52) U.S. Cl. CPC H01J 37/32513; H01J 2237/3341; H01J 37/32642; H01J 37/32715

(57) ABSTRACT

There is provision of a substrate support assembly on which a substrate to be subjected to plasma processing in a processing chamber is placed. The substrate support assembly includes a base, an electrostatic chuck on which the substrate and an edge ring surrounding the substrate are placed, and a sealing member. The electrostatic chuck is disposed on the base via an adhesive layer, and the sealing member is in contact with a back surface of the edge ring to seal a space to which the adhesive layer is exposed.

### CROSS-REFERENCE TO RELATED APPLICATIONS

This patent application is based upon and claims priority to Japanese Patent Application No. 2015-191958 filed on Oct. 21, 2019, the entire contents of which are incorporated herein by reference.

### TECHNICAL FIELD

The present disclosure relates to a substrate support assembly, a substrate processing apparatus, and a sealing member.

### BACKGROUND

For example, Patent Document 1 describes that a coating member is provided around a bonding layer bonding an electrostatic chuck layer to a support, to reduce degradation of the bonding layer caused by active species generated by a plasma. Patent Document 2 describes an electrostatic chuck that electrostatically attracts a focus ring (edge ring) to the electrostatic chuck.

### RELATED ART DOCUMENTS

### Patent Documents

[Patent Document 1] Japanese Laid-open Patent Application Publication No. 2005-033181
[Patent Document 2] Japanese Laid-open Patent Application Publication No. 2010-183074

### SUMMARY

The present disclosure provides a technique for preventing wear of an adhesive that bonds an electrostatic chuck to a support.

According to one aspect of the present disclosure, there is provision of a substrate support assembly on which a substrate to be subjected to plasma processing in a processing chamber is placed. The substrate support assembly includes a base, an electrostatic chuck on which the substrate and an edge ring surrounding the substrate are placed, and a sealing member. The electrostatic chuck is disposed on the base via an adhesive layer, and the sealing member is in contact with a back surface of the edge ring to seal a space to which the adhesive layer is exposed.

### BRIEF DESCRIPTION OF THE DRAWINGS

FIG. 1 is a cross-sectional view illustrating a schematic configuration of a substrate processing apparatus according to an embodiment;

FIG. 2 is a diagram illustrating a mounting table assembly of the substrate processing apparatus according to the embodiment;

FIG. 3 is a diagram, illustrating behavior of radicals in a plasma during plasma processing in the substrate processing apparatus according to the embodiment;

FIG. 4 is a diagram illustrating a first variation of the mounting table assembly of the substrate processing apparatus according to the embodiment;

FIG. 5 is a diagram illustrating a second variation of the mounting table assembly of the substrate processing apparatus according to the embodiment;

FIG. 6 is a diagram illustrating a third variation of the mounting table assembly of the substrate processing apparatus according to the embodiment;

FIG. 7 is a diagram illustrating a mounting table assembly of a substrate processing apparatus according to a comparative example; and

FIG. 8 is a diagram illustrating behavior of radicals in a plasma during plasma processing in the substrate processing apparatus according to the comparative example.

### DETAILED DESCRIPTION Of EMBODIMENTS

Hereinafter, embodiments for carrying out the present disclosure will be described with reference to the drawings. Note that in the present specification and drawings, elements having substantially identical features are given the same reference symbols, and redundant descriptions will be omitted.

### <Overall Configuration of Substrate Processing Apparatus>

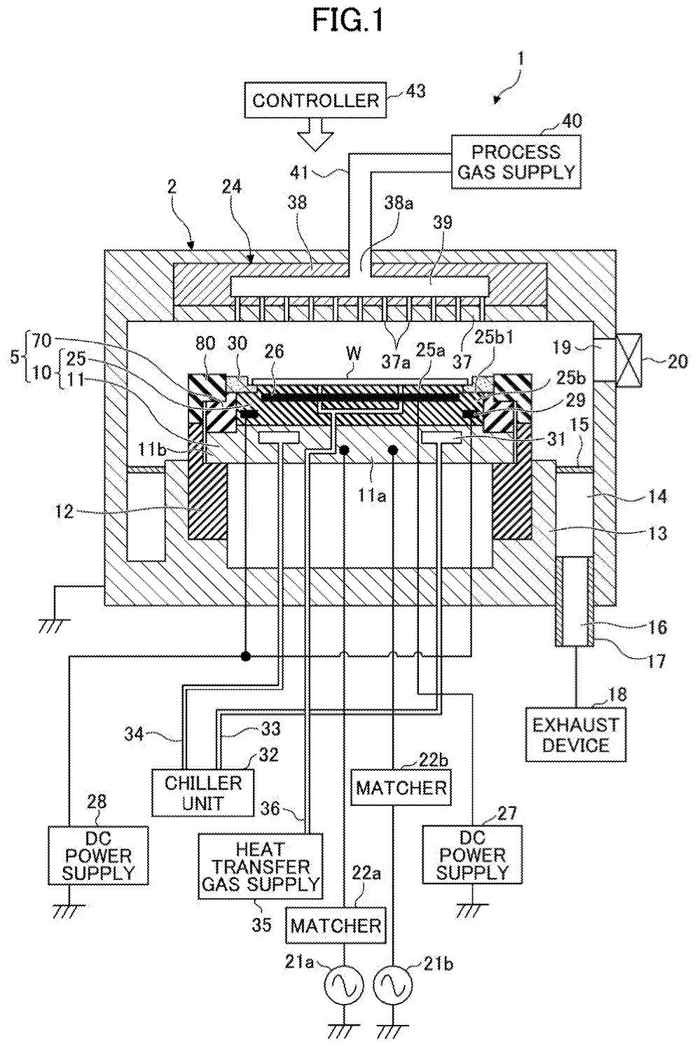

First, an example of the overall configuration of a substrate processing apparatus 1 will be described with reference to FIG. 1. FIG. 1 is a cross-sectional view illustrating the schematic configuration of the substrate processing apparatus 1 according to the present embodiment. In the present embodiment, a case in which the substrate processing apparatus 1 is an RIE (Reactive Ion Etching) type substrate processing apparatus will be described. However, the substrate processing apparatus 1 may be a plasma etching apparatus or a plasma CVD (Chemical Vapor Deposition) apparatus.

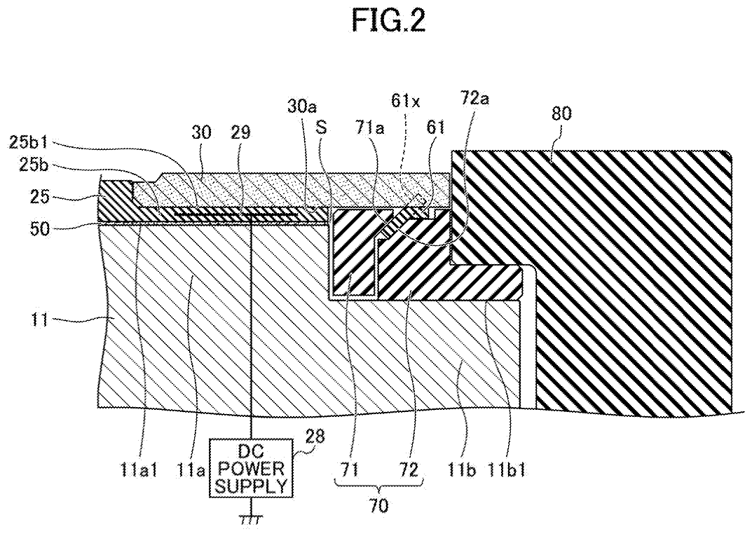

In FIG. 1, the substrate processing apparatus 1 includes a cylindrical processing vessel 2 made of metal such as aluminum or stainless steel. The processing vessel 2 is electrically grounded, and a disc-shaped mounting table 10 on which a substrate W is placed is provided within the processing vessel 2. The interior of the processing vessel 2 is an example of a process chamber in which a substrate is placed. The mounting table 10 may also be referred to as a “substrate support 10”. The mounting table 10 includes a base 11 and an electrostatic chuck 25. A combination of the mounting table 10 and an annular sealing member 61 (FIG. 2), which will be described below, or a combination of the mounting table 10, the annular sealing member 61, and a ring member 70 to be described below may be referred to as a “mounting table assembly 5” or a “substrate support assembly 5”. An edge ring 30 may also be referred to as a focus ring. The base 11 functions as a bottom electrode. The base 11 is made of aluminum for example, and is supported by a cylindrical support 13 which extends vertically upward from the bottom of the processing vessel 2, via a cylindrical insulating retainer 12. The base 11 includes a central member 11a on which an electrostatic chuck 25 is placed, and an annular peripheral member 11b surrounding the central member 11a. On the peripheral member 11b of the base 11, the ring member 70 is placed. The ring member 70 is an insulator. At the periphery of the edge ring 30 and the ring member 70, a covering member 80 is provided. The ring member 70 includes a first ring member 71 and a second ring member 72 as described below, but the first ring member 71 and the second ring member 72 are collectively described as the ring member 70 in FIG. 1. Details of the ring member 70 and the covering member 80 are described below.

An exhaust passage 14 is formed between the inner side wall of the processing vessel 2 and the outer side wall of the cylindrical support 13, and an annular baffle plate 15 is disposed at the inlet or midway of the exhaust passage 14. Also, an exhaust port 16 is disposed at the bottom of the exhaust passage 14, and an exhaust device 18 is connected to the exhaust port 16 via an exhaust pipe 17. Here, the exhaust device 18 includes a dry pump and a vacuum pump to reduce the pressure in a processing space of the processing vessel 2 to a predetermined level. The exhaust pipe 17 also includes an automatic pressure control valve (hereinafter referred to as “APC”) which is a variable butterfly valve, and the APC automatically controls the pressure in the processing vessel 2. Further, a gate valve 20 for opening and closing a loading/unloading port 19 for the substrate W is attached to the side wall of the processing vessel 2.

A first radio frequency power supply 21a is connected to the base 11 via a first matcher 22a. A second radio frequency power supply 21b is connected to the base 11 through a second matcher 22b. The first radio frequency power supply 21a supplies, to the base 11, radio frequency power at a first predetermined frequency (e.g., 100 MHz) for plasma generation. The second radio frequency power supply 21b supplies radio frequency power for ion retraction to the base 11, at a second predetermined frequency lower than the first predetermined frequency (e.g., 13 MHz).

A showerhead 24, which also functions as an upper electrode, is disposed at the ceiling of the processing vessel 2. This causes two types of high frequency voltage to be applied between the base 11 and the showerhead 24, from the first and second radio frequency power supplies 21a and 21b.

The electrostatic chuck 25 is provided on the upper surface of the base 11 to attract the substrate W by electrostatic attractive force. The electrostatic chuck 25 is secured to the base 11 via an adhesive layer 50 (FIG. 2). The electrostatic chuck 25 includes a disc-like central portion 25a on which the substrate W is placed, and an annular peripheral portion 25b which is formed to surround the central portion 25a. The central portion 25a protrudes upward in the drawing, with respect to the peripheral portion 25b. On a mounting surface 25b1 of the peripheral portion 25b, the annular edge ring 30 that surrounds the central portion 25a is mounted. Also, the central portion 25a is formed by inserting an electrode plate 26 made of a conductive film between a pair of dielectric films.

The peripheral portion 25b is formed by inserting an electrode plate 29 made of a conductive film between a pair of dielectric films. A direct-current (DC) power supply 27 is electrically connected to the electrode plate 26. A DC power supply 28 is electrically connected to the electrode plate 29. The DC power supply 27 and the DC power supply 28 are capable of changing magnitude and polarity of DC voltage supplied. The DC power supply 27 applies DC voltage to the electrode plate 26 under the control of a controller 43, which will be described below. The DC power supply 28 applies DC voltage to the electrode plate 25 under the control of the controller 43. As voltage is applied to the electrode plate 26 from the DC power supply 27, the electrostatic chuck 25 generates electrostatic force, i.e., Coulomb force, and the substrate W is attracted and held to the electrostatic chuck 25 by the electrostatic force. The electrostatic chuck 25 also generates electrostatic force, i.e., Coulomb force, by voltage applied to the electrode plate 29 from the DC power supply 28, and the edge ring 30 is attracted and held to the electrostatic chuck 25 by the electrostatic force.

Inside the base 11, an annular refrigerant chamber 31 that extends circumferentially is provided, for example. A chiller unit 32 supplies a refrigerant at a predetermined temperature, such as cooling water, to the refrigerant chamber 31 in a circulating manner through pipes 33 and 34, and a processing temperature of the substrate w on the electrostatic chuck 25 is controlled by the refrigerant. The refrigerant is a temperature adjusting medium that circulates in the refrigerant chamber 31 via the pipes 33 and 34. The temperature adjusting medium not only cools the base 11 and the substrate W, but may also heat them.

A heat transfer gas supply 35 is connected to the electrostatic chuck 25 via a gas supply line 36 The heat transfer gas supply 35 supplies a heat transfer gas to a space between the central portion 25a of the electrostatic chuck 25 and the substrate W, through the gas supply line 36. As the heat transfer gas, a heat conductive gas, such as He gas is preferably used.

The showerhead 24 at the ceiling includes an electrode plate 37 having a large number of gas holes 37a and an electrode support 38 detachably supporting the electrode plate 37. The electrode plate 37 is provided at the bottom surface of the electrode support 38. A buffer chamber 39 is provided within the electrode support 38, and a gas inlet 38a is provided at the upper surface of the buffer chamber 39. A process gas supply 40 is connected to the gas inlet 38a via a gas supply line 41.

Each component of the substrate processing apparatus 1 is coupled to the controller 43. For example, the exhaust device 18, the first radio frequency power supply 21a, the second radio frequency power supply 21b, the DC power supply 27, the DC power supply 28, the chiller unit 32, the heat transfer gas supply 35, and the process gas supply 40 are coupled to the controller 43. The controller 43 controls each of the components of the substrate processing apparatus 1.

The controller 43 includes a central processing unit (CPU) and a storage device such as a memory, which are not illustrated. The controller 43 causes the substrate processing apparatus 1 to perform desired processes, by the CPU reading out and executing a program and a process recipe stored in the storage device. For example, an electrostatic attracting process for attracting the edge ring 30 electrostatically is performed in the substrate processing apparatus 1, by the controller 43.

In the substrate processing apparatus 1, when performing dry etching, the gate valve 20 is first opened, and a substrate W to be processed is loaded into the processing vessel 2 and placed on the electrostatic chuck 25. Subsequently, in the substrate processing apparatus 1, a process gas (for example, a mixture of C₄F₈ gas, O₂ gas, and Ar gas) is introduced into the processing vessel 2 at a predetermined flow rate and flow rate ratio from the process gas supply 40, and the pressure in the processing vessel 2 is set to a predetermined value by the exhaust device 18.

Next, in the substrate processing apparatus 1, different types of radio frequency electric power each having a different frequency are supplied to the base 11 from the first radio frequency power supply 21a and the second radio frequency power supply 21b, respectively. Also, in the substrate processing apparatus 1, DC voltage is applied to the electrode plate 26 of the electrostatic chuck 25 from the DC power supply 27 to attract the substrate W to the electrostatic chuck 25. Further, in the substrate processing apparatus 1, DC voltage is applied from the DC power supply 28 to the electrode plate 29 of the electrostatic chuck 25 to attract the edge ring 30 to the electrostatic chuck 25. The process gas discharged from the showerhead 24 is formed into a plasma, and etching treatment is applied to the substrate W by radicals and ions in the plasma.

### <Sealing Member of Edge Ring>

FIG. 2 is a diagram illustrating the mounting table assembly of the substrate processing apparatus according to the embodiment. FIG. 2 is an enlarged cross-sectional view of a part of the substrate processing apparatus 1 corresponding to the edge ring 30.

The edge ring 30 is placed on the electrostatic chuck 25, and is held electrostatically. The electrostatic chuck 25 is bonded to and secured to the base 11 via the adhesive layer 50.

Each part will be described in detail below.

The base 11 includes the central member 11a and the peripheral member 11b formed lower than the upper surface 11a1 of the central member 11a. The electrostatic chuck 25 is placed on the upper surface 11a1 of the central member 11a of the base 11. The electrostatic chuck 25 is secured to the upper surface 11a1 of the central member 11a of the base 11 by the adhesive layer 50. In this manner, the electrostatic chuck 25 is provided on the base 11 via the adhesive layer 50. As illustrated in FIG. 1, the electrostatic chuck 25 includes the electrode plate 26 and the electrode plate 29, and the electrode plate 26 and the electrode plate 29 respectively attract the substrate W and the edge ring 30 electrostatically, by DC voltage being applied to the respective electrode plates.

The ring member 70 is placed on the upper surface 11b1 of the peripheral member 11b of the base 11. The ring member 70 includes the first ring member 71 and the second ring member 72. The first ring member 71 has a slanted surface 71a. The second ring member 72 also has a slanted surface 72a. The slanted surface 71a of the first ring member 71 and the slanted surface 72a of the second ring member 72 are inclined at the sane inclination angle in the cross-sectional view, so as to extend outward from the bottom to the top. The first ring member 71 is disposed over the second ring member 72 such that the annular sealing member 61 is sandwiched between the slanted surface 71a and the slanted surface 72a.

The annular sealing member 61 is an annular member whose cross section passing through the central axis of the annular sealing member 61 has a tapered shape. In the cross-sectional view, the annular sealing member 61 extends outward from the bottom to the top. In other words, the annular sealing member 61 is formed such that the diameter of the annular sealing member 61 (i.e., a horizontal, distance from the central axis of the annular sealing member 61 to the lateral surface of the annular sealing member 61) gradually increases toward the top of the annular sealing member 61 from the bottom. However, the annular sealing member 61 may be an annular member having a tapered cross section passing through the central, axis of the annular sealing member 61 and extending outward from the top to the bottom m the cross-sectional view. The annular sealing member 61 may also be an inclined or non-inclined annular member that is formed of two layers each connected at the upper end of the layers. The annular sealing member 61 is formed of a material that is resistant to radicals in the plasma, e.g., a tetrafluoroethylene-perfluoro vinyl ether based fluorocarbon rubber (FFKM). The annular sealing member 61 is fixed by sandwiching the annular sealing member 61 between the first ring member 71 and the second ring member 72.

The covering member 80 is a member that holds a part of. the second ring member 72 of the ring member 70 by sandwiching the part of the second ring member 72 between the covering member 80 and the base 11. The ring member 70 is secured to the base 11 by the covering member 80. The part of the second ring member 72 of the ring member 70 is sandwiched by the covering member 80 and the base 11, thereby reducing a gap in a region where the ring member 70 is in contact with the covering member 80. Further, by fixing the ring member 70 to the base 11 with the covering member 80, a gap between the second ring member 72 of the ring member 70 and the base 11 can be reduced. This reduction in gap prevents radicals from passing through the gap between the ring member 70 and the covering member 80 and the gap between the ring member 70 and the base 11.

The edge ring 30 is held electrostatically by the electrostatic chuck 25. Thus, the annular sealing member 61 provided in the ring member 70 comes into contact with the back surface 30a of the edge ring 30 in a state in which the lateral surface of the annular sealing member 61 is inclined, in the cross-sectional view, with respect to the central axis of the electrostatic chuck 25, the edge ring 30, or the annular sealing member 61 (or with respect to the back surface 30a of the edge ring 30). Further, as the annular sealing member 61 is pressed by the edge ring 30, the annular sealing member 61 is deformed elastically from a state 61x of the annular sealing member 61 before deformation. Accordingly, as the back surface 30a of the edge ring 30 is pressed by the annular sealing member 61, the annular sealing member 61 can seal a space between the back surface 30a of the edge ring 30 and the ring member 70. As described above, the annular sealing member 61 seals the space between the back surface 30a of the edge ring 30 and the ring member 70 which is a member facing the back surface 30a of the edge ring 30. Thus, the annular sealing member 61 seals the space S (FIG. 2) to which the adhesive layer 50 is exposed.

In the present embodiment, the edge ring 30 is held electrostatically by the electrostatic chuck 25, but may be held on the electrostatic chuck 25 by the weight of the edge ring 30, for example. In addition, for example, the edge ring 30 may be held by bonding the back surface 30a of the edge ring 30 and the mounting surface 25b1 of the electrostatic chuck 25 with an adhesive sheet.

### <Effect>

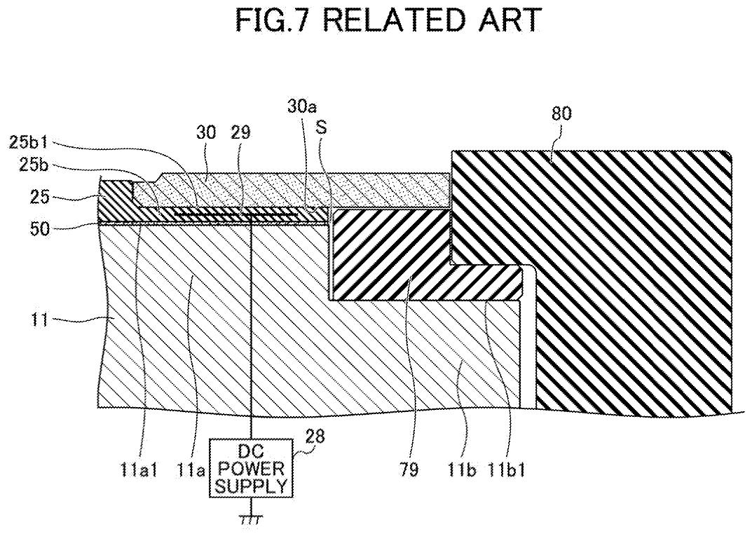

In order to explain the effect of the present embodiment, a substrate processing apparatus according to a comparative example will be described. FIG. 7 is a diagram illustrating a mounting table assembly of the substrate processing apparatus according to the comparative example.

The substrate processing apparatus according to the comparative example differs from the substrate processing apparatus 1 according to the present embodiment in that the substrate processing apparatus according to the comparative example does not include the annular sealing member 61. Also, instead of the ring member 70, the substrate processing apparatus according to the comparative example includes a ring member 79 having a different structure from the ring member 70.

In each of the substrate processing apparatus 1 according to the present embodiment and the substrate processing apparatus according to the comparative example, behavior of radicals in a plasma during plasma processing will be described.

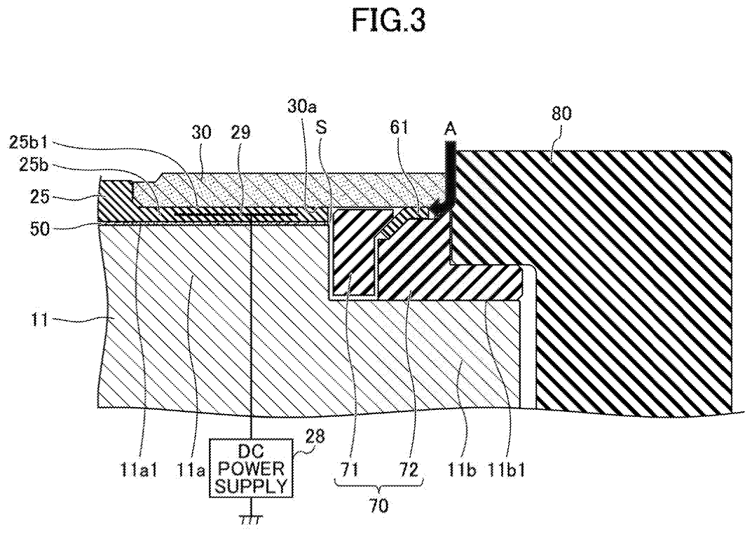

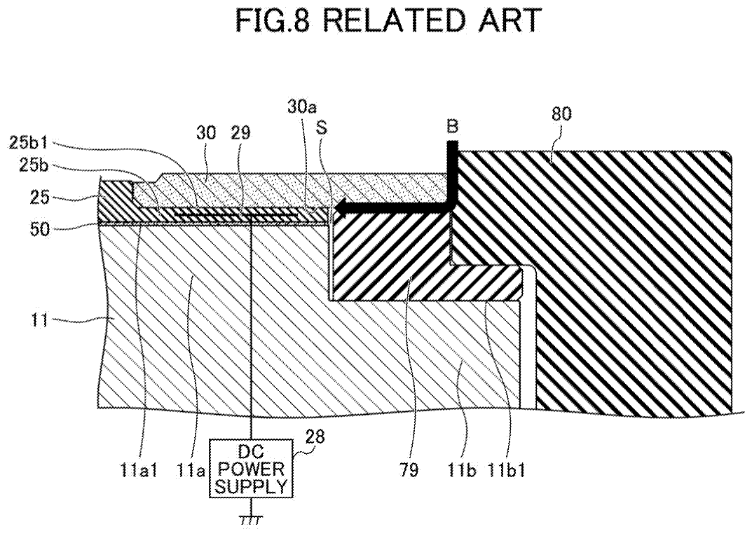

FIG. 3 is a diagram illustrating behavior of radicals in a plasma when plasma processing is performed in the substrate processing apparatus 1 according to the present embodiment. FIG. 8 is a diagram illustrating behavior of radicals in a plasma when plasma processing is performed in the substrate processing apparatus according to the comparative example.

In the substrate processing apparatus 1 according to the present embodiment, even though radicals in the plasma pass through the gap between the edge ring 30 and the covering member 80 and the gap between the edge ring 30 and the ring member 70 as indicated by the arrow A illustrated in FIG. 3, further entry is prevented by the annular sealing member 61. That is, the annular sealing member 61 seals the space S to which the adhesive layer 50 is exposed. Thus, it is possible to prevent, radicals from reaching the adhesive layer 50. Further, because radicals do not reach the adhesive layer 50, degradation of the adhesive layer 50 by radicals can be prevented.

In contrast, in the substrate processing apparatus according to the comparative example, radicals in the plasma enter the space 5 to which the adhesive layer 50 is exposed, by passing through the gap between the edge ring 30 and the covering member 80 and the gap between the edge ring 30 and the ring member 73, as indicated by the arrow B illustrated in FIG. 8. Thus, the adhesive layer 50 is degraded by radicals. Further, for example, the electrodes of the electrostatic chuck 25 may be damaged by the adhesive layer 50 being degraded, which may cause a processing error.

### <First Variation>

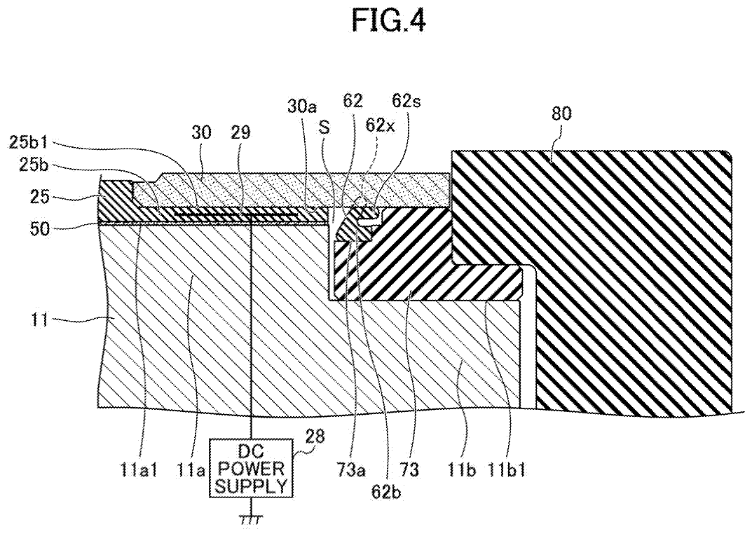

FIG. 4 is a diagram illustrating a first variation of the mounting table assembly of the substrate processing apparatus according to the present embodiment.

In the first variation, an annular sealing member 62 is provided instead of the annular sealing member 61. Also, instead of the ring member 70, a ring member 73 having a different shape from the ring member 70 is provided. The annular sealing member 62 consists of an annular member 62b and an inclined portion 62s disposed on the annular member 62b. The inclined portion 62s has a shape similar to a reversed hollow conical frustum of which the top and bottom are open, and a diameter of the inclined portion 62s (i.e., a horizontal distance from the central axis of the annular sealing member 62 to the inclined portion 62s of the annular sealing member 62) gradually increases from the bottom toward the top. Also, the annular sealing member 62 is formed of a material that is resistant to radicals in the plasma, e.g., a tetrafluoroethylene-perfluoro vinyl ether based fluorocarbon rubber (FFKM). The edge ring 30 is held electrostatically by the electrostatic chuck 25. Thus, the inclined portion 62s of the annular sealing member 62 placed on the ring member 73 contacts the back surface 30a of the edge ring 30 in a state in which the cross section of the inclined portion 62s is inclined with respect to the central axis of the annular sealing member 61 or the edge ring 30 (or with respect to the back surface 30a of the edge ring 30). Further, as the annular sealing member 62 is pressed by the edge ring 30, the annular sealing member 62 is deformed elastically from a state 62x of the annular sealing member 62 before deformation. Thus, as the back surface 30a of the edge ring 30 is pressed by the annular sealing member 62, the annular sealing member 62 can seal a space between the back surface 30a of the edge ring 30 and the ring member 73. In this manner, the annular sealing member 62 seals the space between the back surface 30a of the edge ring 30 and the ring member 73 which is a member facing the back surface 30a of the edge ring 30. Thus, the annular sealing member 62 seals the space S to which the adhesive layer 50 is exposed.

### <Second Variation>

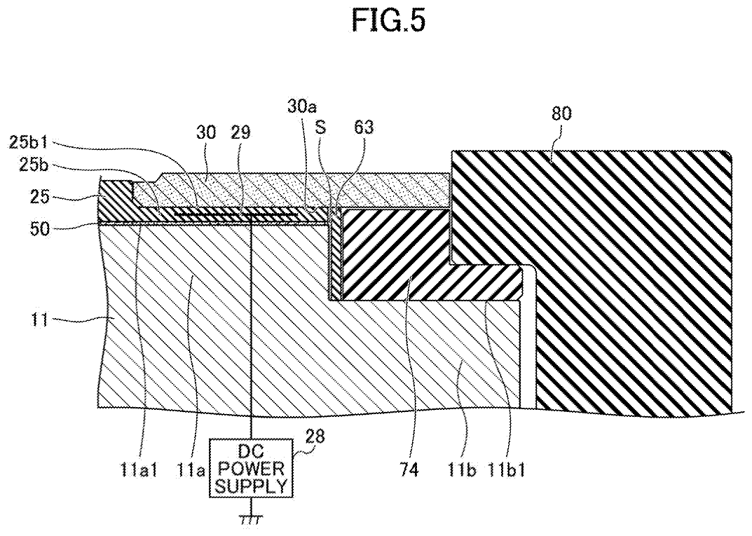

FIG. 5 is a diagram illustrating a second variation of the mounting table assembly of the substrate processing apparatus according to the present embodiment.

In the second variation, an annular (cylindrical) sealing member 63 is provided instead of the annular sealing member 61. Also, instead of the ring member 70, a ring member 74 having a different shape from the ring member 70 is provided. The annular sealing member 63 is disposed on the upper surface 11b1 of the peripheral member 11b of the base 11. Also, the annular sealing member 63 is provided so as to surround the central member 11a of the base 11. The annular sealing member 63 is formed of a material resistant to plasma, for example, a tetrafluoroethylene-perflucre vinyl ether based fluorocarbon rubber (FFKM). The height (i.e., vertical length) of the annular sealing member 63 is greater than a vertical distance between the upper surface 11b1 of the peripheral member 11b of the base 11 and the mounting surface 25b1 of the electrostatic chuck 25. The annular sealing member 63 may be in contact with the central member 11a of the base 11. Additionally, the annular sealing member 63 may be in contact with the adhesive layer 50 or the electrostatic chuck 25. In this case, the side surface of the central member 11a may be compressed by the annular sealing member 63.

The edge ring 30 is held electrostatically by the electrostatic chuck 25. Thus, the annular sealing member 63 placed on the base 11 contacts the back surface 30a of the edge ring 30. Further, as the annular sealing member 63 is pressed by the edge ring 30, the annular sealing member 63 is deformed elastically from a state of the annular sealing member 63 before deformation. Thus, as the back surface 30a of the edge ring 30 is pressed by the annular sealing member 63, the annular sealing member 63 can seal a space between the back surface 30a of the edge ring 30 and the base 11. In this manner, the annular sealing member 63 seals the space between the back surface 30a of the edge ring 30 and the base 11 which is a member facing the back surface 30a of the edge ring 30. Thus, the annular sealing member 63 seals the space S to which the adhesive layer 50 is exposed.

### <Third Variation>

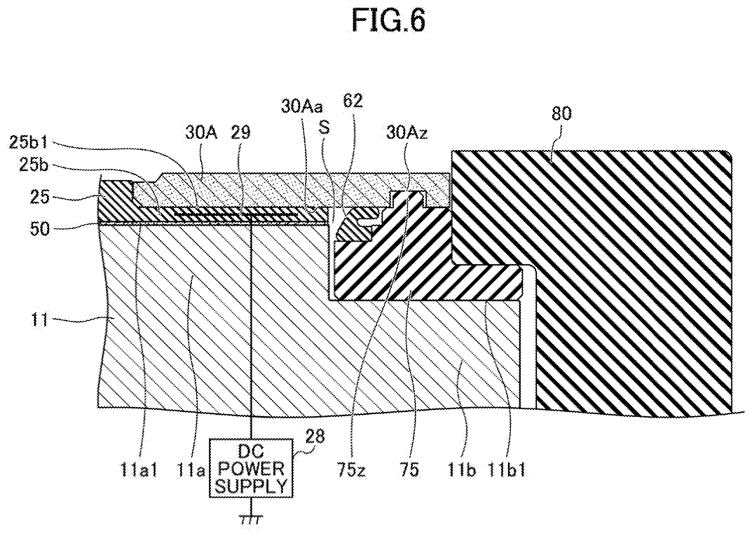

FIG. 6 is a diagram illustrating a third variation of the mounting table assembly of the substrate processing apparatus according to the present embodiment.

In the third variation, in addition to the annular sealing member 62 of the first variation, a labyrinth sealing member is provided. A groove 30Az is circumferentially formed on the back surface 30Aa of the edge ring 30A. further, on a portion of a ring member 75 corresponding to the groove 30Az of the edge ring 30A, an annular projection 75z is formed in a circumferential direction. When the edge ring 30A is placed on the electrostatic chuck 25, the annular projection 75z of the ring member 75 is fitted into the groove 30Az of the edge ring 30A, to form the labyrinth sealing member. This further prevents entry of radicals. The labyrinth sealing member may be applied not only to the first variation, but also to the embodiment as illustrated in FIG. 2 or the second variation illustrated in FIG. 5.

### <Other Variations>

The annular sealing member may be formed in any shape as long as a portion of the annular sealing member contacts the edge ring so as to press the edge ring. For example, the lateral surface of the annular sealing member 61 may be inclined in the cross-sectional view such that the diameter of the annular sealing member 61 (i.e., a horizontal distance from the central axis of the annular sealing member 61 to the lateral surface of the annular sealing member 61) gradually decreases toward the top of the annular sealing member 61 from the bottom. In this case, the slanted surface 71a of the first ring member 71 and the slanted surface 72a of the second ring member 72 are inclined at the same inclination angle relative to the vertical direction, such that the diameters of the first and second ring members 71 and 72 (i.e., horizontal distances from the central axis of the ring member 70 to the slanted surfaces 71a and 72a) decrease toward the top of the ring member 70 from the bottom. The second ring member 72 is mounted on the first ring member 71 such that the annular sealing member 61 is sandwiched between the slanted surface 72a and the slanted surface 72a. Similarly, with respect to the inclined portion 62s of the annular sealing member 62 according to the first variation, the inclined portion 62s may also be inclined such that the diameter of the inclined portion 62s decreases toward the top of the inclined portion 62s from the bottom. The annular sealing member may also be configured such that the annular sealing member contacts the edge ring at a part different from the end (upper end) of the annular sealing member. For example, a groove for an O-ring may be provided on the ring member or the edge ring, and an O-ring may be used as the annular sealing member. A material or a shape of the annular sealing member may be determined such that the focus ring is not lifted from the electrostatic chuck by elastic force of the annular sealing member when the annular sealing member is deformed by being pressed by the focus ring.

The mounting table, the substrate processing apparatus, and the edge ring according to the present embodiment and its variations that have been disclosed herein should be considered exemplary in ail respects and not limiting. The above embodiment and its variations may be modified and enhanced in various forms without departing from the appended claims and spirit thereof. Matters described in the above embodiment and its variations may take other configurations to an extent not inconsistent, and may be combined to an extent not inconsistent.

The substrate processing apparatus of the present disclosure is applicable to any of the following types of processing apparatuses: a capacitively coupled plasma (CCP) type processing apparatus, an inductively coupled plasma (ICP) type processing apparatus, a processing apparatus using a radial line slot antenna (RLSA), an electron cyclotron resonance plasma (ECR) type processing apparatus, and a helicon wave plasma (HWP) type processing apparatus.

What is claimed is:

1. A substrate support assembly on which a substrate to be subjected to plasma processing is placed in a processing chamber, the substrate support assembly comprising:
a base;
an electrostatic chuck on which the substrate and an edge ring surrounding the substrate are placed, the electrostatic chuck being disposed on the base via an adhesive layer; and
a sealing member in contact with a back surface of the edge ring to seal a space to which the adhesive layer is exposed.

2. The substrate support assembly according to claim 1, further comprising:
a ring member provided between the edge ring and the base; wherein
the sealing member is provided between the edge ring and the ring member.

3. The substrate support assembly according to claim 1, wherein an end of the sealing member is in contact with the back surface of the edge ring.

4. The substrate support assembly according to claim 1, wherein the sealing member is in contact with the back surface of the edge ring in a state in which a lateral surface of the sealing member is inclined with respect to the back surface of the edge ring in a cross-sectional view.

5. The substrate support assembly according to claim 4, wherein
the sealing member is annular, and
a diameter of the sealing member gradually increases toward an upper end of the sealing member.

6. A substrate processing apparatus comprising the substrate support assembly according to claim 1, wherein the substrate processing apparatus is configured to apply the plasma processing to the substrate placed in the processing chamber.

7. A sealing member used for a substrate support assembly, the substrate support assembly including a base and an electrostatic chuck on which a substrate and an edge ring surrounding the substrate are placed, the electrostatic chuck being disposed on the base via an adhesive layer, wherein
the sealing member is in contact with a back surface of the edge ring in a state in which a lateral surface of the sealing member is inclined with respect to the back surface of the edge ring in a cross-sectional view, to seal a space to which the adhesive layer is exposed.
